(19) United States
(12) Patent Application Publication
(10) Pub. No.: US 2026/0310861 A1
(43) Pub. Date: Oct. 8, 2026

(54) CONTEXT-BASED METROLOGY IMPUTATION FOR IMPROVED PERFORMANCE OF COMPUTATIONAL GUIDED SAMPLING

(71) Applicant: ASML Netherlands B.V., Veldhoven (NL)

(72) Inventors: Chenxi LIN, Newark, CA (US); Zhihuan WANG, Mountain View, CA (US); Yi ZOU, Foster City, CA (US)

(73) Assignee: ASML Netherlands B.V., Veldhoven (NL)

(21) Appl. No.: 19/481,344

(22) PCT Filed: Apr. 4, 2024
(86) PCT No.: PCT/EP2024/059269

§ 371 Date: Nov. 4, 2025

Related U.S. Application Data
(60) Provisional application No. 63/464,047, filed on May 4, 2023.

(51) Int. Cl. G06F 30/27

(52) U.S. Cl. CPC G06F 30/27

(57) ABSTRACT

A method to identify a location on a wafer with a computational model to scan using an inspection tool is disclosed. More particularly, a method of correlating metrology data and context data to impute missing metrology data necessary to train as well as apply a computational model for guided inspection is disclosed. A computational probability prediction model is disclosed to generate defective die probability estimates with improved accuracy and versatility to guide different wafers for inspection.

### CROSS-REFERENCE TO RELATED APPLICATION

This application claims priority to U.S. Application No. 63/464,047 which was filed on 4 May 2023, and which is incorporated herein in its entirety by reference.

### TECHNICAL FIELD

The embodiments provided herein relate to identifying a location on a wafer with a computational model, and more particularly to a method to correlate metrology data and context data to impute missing metrology data for a wafer to train a computational guided inspection model and improve model performance.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Various metrology tools are developed and used to check whether the ICs are correctly manufactured. To improve defect inspection performance, a computational guided inspection (CGI) machine learning model may be used to assist the tools by indicating areas of a wafer to be inspected.

### SUMMARY

The embodiments provided herein disclose a method to identify a location on a wafer using a computational model, and more particularly, a method of correlating wafer data to impute missing metrology data to train the computational model for improved defective die probability modeling.

Some embodiments provide an apparatus for identifying a location on a wafer to scan during inspection using a computational defect probability model comprising a memory storing a set of instructions and at least one processor configured to execute the set of instructions to cause the apparatus to perform a method for identifying a location on a wafer to scan during inspection using a computational defect probability model. The method comprises obtaining initial metrology data and initial context data for a plurality of initial wafers, correlating the initial metrology data and initial context data for each wafer of the plurality of initial wafers, correlating a subsequent wafer with the plurality of initial wafers based on context data of the subsequent wafer and the initial context data of the plurality of initial wafers, and selecting a location on the subsequent wafer to scan using an inspection tool based on the correlation.

In some embodiments, a non-transitory computer readable medium comprising a set of instructions that is executable by one or more processors of a computing device to cause the computing device to perform a method for identifying a location on a wafer to scan during inspection is provided. The method comprises obtaining initial metrology data and initial context data for a plurality of wafers, correlating the initial metrology data and initial context data for each wafer of the plurality of wafers, imputing missing data from the plurality of wafers using the correlated initial metrology data and initial context data, and training a computational defect probability model with the imputed missing data and initial metrology data and initial context data for the plurality of wafers.

Other advantages of the present disclosure will become apparent from the following description taken in conjunction with the accompanying drawings wherein are set forth, by way of illustration and example, certain embodiments of the present disclosure.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example multi-beam tool that can be a part of the example charged-particle beam inspection system of FIG. 1, consistent with embodiments of the present disclosure.

FIG. 3 is a schematic block diagram illustrating throughput to generate input data, consistent with embodiments of the present disclosure.

FIG. 4 is an example block diagram illustrating training of a CGI model using an initial training dataset.

FIG. 5 is an example diagram illustrating down sampling at the wafer lot level to acquire input metrology data for the CGI model.

FIG. 6 is an example block diagram illustrating a system to train a computational model, consistent with embodiments of the present disclosure.

FIGS. 7A and 7B are example illustrations of imputing information for wafers, consistent with embodiments of the present disclosure.

FIG. 8 is an example block diagram illustrating a system to apply a trained computational model to guide inspection of a wafer, consistent with embodiments of the present disclosure.

FIG. 9 is an example flow diagram illustrating a method to generate a context linked model to impute missing input data to train a CGI model and using the CGI model to generate a sampling plan for wafer inspection, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged-particle beams (e.g., including protons, ions, muons, or any other particle carrying electric charges) may be similarly applied. Furthermore, other imaging systems may be used, such as optical imaging, photon detection, x-ray detection, ion detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. The enhanced computing power of electronic devices, while reducing the physical size of the devices, can be accomplished by significantly increasing the packing density of circuit components such as transistors, capacitors, diodes, etc. on an IC chip. For example, an IC chip of a smart phone, which is the size of a thumbnail, may include over 2 billion transistors, the size of each transistor being less than 1/1000th of a human hair.

ICs may be manufactured using lithography, which is a fabrication process involving creating complex circuit patterns drawn on a mask deposited onto a substrate. Lithography may be performed by a lithographic apparatus, which is a machine that applies a source of radiation (e.g., light or X-ray) onto a target portion of the substrate to form a desired pattern. The target portion of the substrate may be covered with a pattern device (e.g., mask) that may be either eliminated or developed after exposure to the radiation source. This process of transferring the desired pattern to the substrate is called a patterning process. The patterning process may include a patterning step to transfer a pattern from a pattern device (e.g., a mask) to the substrate. There can also be one or more related pattern processing steps, such as mask development by a development apparatus, baking of the substrate using a bake tool, etching the pattern onto the substrate using an etch apparatus, or other chemical and physical processing steps involved in fabricating a pattern onto the substrate. Variations in experimental parameters (e.g., stochastic variations, errors, or noise due to an inspection tool or pattern processing tool) can potentially limit lithography implementation for high volume manufacturing (HVM), or process yield, of ICs and introduce defects into IC structures.

In the manufacture of ICs using a lithographic apparatus, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers. For this purpose, the substrate is provided with one or more sets of alignment marks. Each mark is a structure having a position that can be measured later using, for example, an electron beam inspection tool. Defects may occur in which an applied pattern structure or pattern layer is incorrectly placed in relation to a reference mark, or when the fabrication conditions are suboptimal. A reference mark or layout define the desired structure, structure dimensions, and the distance between IC structures (such as gates, capacitors, etc.) or interconnect lines. This may ensure that the IC devices or lines do not interact with one another in an undesirable way. The structure limitations provided by the reference layouts are typically referred to as critical dimensions. A critical dimension of a circuit can be defined as the smallest width of a line or hole or the smallest space between two lines or two holes. Thus, the critical dimension determines the overall size and packing density of the designed IC. A goal in IC fabrication is to faithfully reproduce the original IC design on the substrate. If an error occurs during fabrication where the created IC design pattern does not match the reference design, this may result in a defect in the IC structure and render the IC inoperable.

Making these ICs with extremely small structures or components is a complex, time-consuming, and expensive process, often involving hundreds of individual steps. Errors in even one step have the potential to dramatically affect the function of the final product. Even one “killer defect” can cause device failure. The goal of the manufacturing process is to improve the overall yield of the process. For example, for a 50-step process to get to a 75% yield, each individual step must have a yield greater than 99.4%, and if the individual step yield is 95%, the overall process yield drops to 7%.

While high process yield is desirable in an IC chip manufacturing facility, maintaining a high wafer throughput, defined as the number of wafers processed per hour, is also essential. High process yields and high wafer throughput can be impacted by the presence of defects, especially if operator intervention is required for reviewing the defects. Thus, high throughput detection and identification of micro and nano-sized defects is desired. One component of improving process yield and wafer throughput may be monitoring the IC fabrication process to ensure a desired number of defect-free ICs are produced. One way to monitor the fabrication process is to inspect the chip circuit structures at various stages of fabrication. Inspection using tools such as, for example, a charged particle beam inspection tool may be used to this effect to maintain high process yield and high wafer throughput. Inspection of a wafer using an electron beam inspection tool may generate images of the wafer to measure IC structure dimensions. The measured dimensions may be compared to a reference structure absent any defects to determine the presence of defects in the imaged structure. If the structure is defective, then the fabrication process can be adjusted, so the defect is less likely to recur. However, as wafers may contain up to 1 billion IC structures, inspection of ICs for defect detection is often a time-consuming process and may not inspect a wafer at a correct location to identify a defect.

Computational guided inspection (CGI) processes guide inspection tools to locations on a wafer where there is a higher probability of defects. A machine learning-based CGI model receives input from various data sources, such as wafer characteristic data (which may include scanner data, metrology data, and fabrication process data) to train the model with inspection results. A CGI machine learning model may be built and used to output a sampling plan indicating a location on a wafer where defects have likely formed after a wafer processing step, so the inspection tool will go to the sampling location to inspect with a higher efficiency than inspecting wafer locations based on experience (e.g., a history of prior defects detected during scanning). The CGI process occurs in-line with wafer fabrication and increases inspection tool efficiency by increasing the accuracy of finding defects on the wafer with capture rates of finding defects higher than a baseline value. The inspection results may be used to confirm a satisfactory wafer yield is maintained throughout manufacturing and to project the failure rate, or die loss per wafer, at the end of production. This projected failure rate may be compared to the results of a wafer probe test, which determines a failure rate for each die fabricated on the wafer. A final metric of a CGI model use case may be the R² correlation score between the estimated and measured die defects for a wafer.

A CGI model may be applied to characteristic wafer data to estimate a defect probability for each die on a wafer. A sampling plan optimizer or sampling plan generator then aggregates the estimated defective die probability for each die on a wafer to generate a defective die probability map, or a sampling plan. The sampling plan may be generated according to input information that defines a predetermined wafer region definition and sampling budget per wafer region. The sampling plan may then be used to guide an inspection tool (e.g., a scanning electron microscope, SEM, or an optical tool) to a region on the wafer where the sampling plan has a set number of dies to inspect (e.g., a sampling budget). The inspection results obtained via the sampling plan indicate a number of actual defective die present, and the inspection results may then be used to project an estimated die loss for a wafer. Accordingly, the CGI-generated sampling plan used to guide inspection may be referred to as the “verified sampling plan.” An R² correlation score for the defective die projection provided by the CGI model sampling plan may be determined by collecting the “ground truth” results for a wafer. The “ground truth” results indicate the actual defective die results of a wafer at the end of production and correspond to a probe test result for a fully completed wafer. Accordingly, a probe test result provides accurate identification of defects for each die on a wafer. The final metric of the CGI model may be the correlation R² score between the projected estimated die loss determined by the CGI model and the actual die loss determined by the probe test results.

Generally, the wafers that are selected for obtaining metrology information during HVM are down-sampled at the wafer/batch level. In other words, only a few wafers out of a 25-wafer batch may be measured to obtain metrology data after each processing step. Thus, the metrology data available as input data for the CGI model may be sparse. More importantly, there is no guarantee that the same wafer will be sampled for metrology after different processing steps in HVM. Therefore, the metrology information for different wafers at all processing steps during wafer fabrication may be missing to various degrees. As a result, there may be an insufficient or incomplete input dataset available to train the CGI model. This may negatively impact the accuracy and robustness of the CGI defect location prediction model and result in suboptimal wafer yield during HVM.

Embodiments of the present disclosure may provide a method to impute input data for the CGI model and improve defect prediction accuracy. In some embodiments, the present disclosure may provide a method to impute missing metrology information. In some embodiments, the present disclosure may provide a method to link metrology information to context information for the imputation. In some embodiments, a wafer without available metrology data may be correlated with wafers with available metrology data, and the correlated data may be used to optimize location selection for guiding an inspection tool. Thus, an R² correlation score may be improved.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

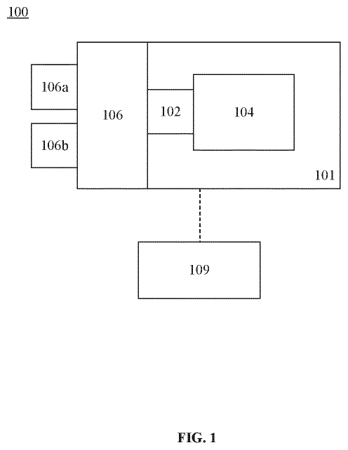

FIG. 1 illustrates an example electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for wafer processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

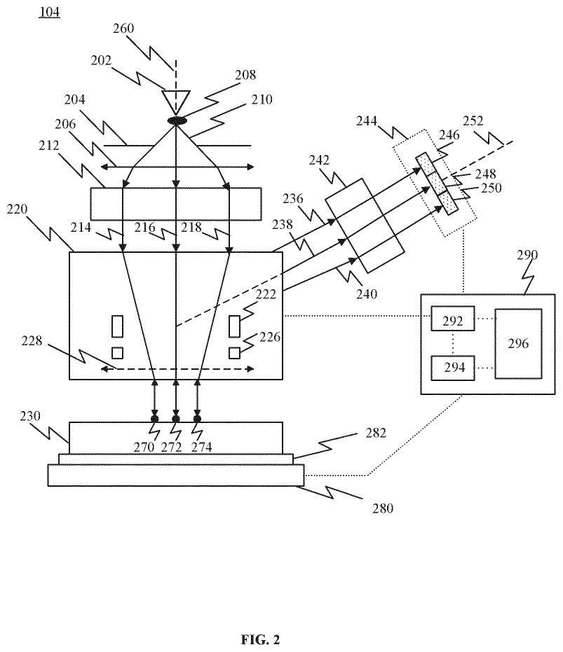

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, the apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and Ses depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and Ses may be more or fewer (or even the same) than the injected electrons of primary charged-particle beam 210.

The images generated by SCPM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SCPM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

Although reference may be made in the present disclosure to ICs, it is appreciated that the present disclosure may be applicable to other possible applications or designs. For example, the present disclosure may be applied to integrated optical systems, magnetic domain memories, liquid-crystal display panels, thin-film magnetic heads, and other nanoscale structures. It is further appreciated that the terms “die”, “structure”, and “IC structure” are used interchangeably in this disclosure.

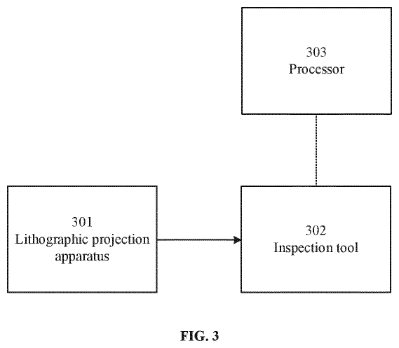

Reference is now made to FIG. 3, which is an example block diagram for generating input data, consistent with embodiments of the present disclosure. Input data may be generated using two steps as illustrated in FIG. 3. A lithographic projection apparatus 301 may be used to fabricate a wafer at a constant fabrication condition (e.g., a focus and dose for a radiation source). An inspection tool 302 (e.g., EBI system 100 in FIG. 1 or multi-beam tool 104 in FIG. 2) may be used to measure metrology information of structures formed on the wafer that was generated by lithographic projection apparatus 301. Metrology information may include, but is not limited to, necking, line pull back, line thinning, critical dimension, edge placement, overlapping, resist top loss, resist undercut, missing defects, and bridging defects of an IC structure on a wafer. A processor 303 (e.g., controller 109 in FIG. 1) with a memory may be communicatively connected to inspection tool 302 to store the measured metrology information.

The images generated by inspection tool 302 may be used for wafer inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, inspection tool 302 may scan multiple regions of the wafer, each region including a test device region designed as the same and generate multiple images capturing those test device regions as manufactured. The multiple images may be compared with each other. If a difference between the multiple images exceeds a tolerance level, a potential defect may be identified.

In some embodiments, processor 303 may be a generic or specific electronic device capable of manipulating or processing information. For example, processor 303 may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. Processor 303 may also be a virtual processor that includes one or more processors distributed across multiple machines or devices coupled via a network.

In some embodiments, processor 303 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

Conventional computational guided inspection (CGI) processes guide inspection tools to locations on a wafer where there is a higher probability of defects. As described above, a machine learning-based CGI model receives input from various data sources, including wafer characteristic data such as scanner data, metrology data, and fabrication process data to train the model with inspection results. A CGI machine learning model may be built and used to output a sampling location on the wafer, so the inspection tool will go to the sampling location to inspect with a higher efficiency than inspecting wafer locations based on experience (e.g., a history of prior defects in a given location detected during scanning). Thus, the CGI model may use input data from a reference wafer (e.g., a reference pattern, metrology information, etc., according to a fabrication or wafer processing step) to thus guide future inspection of wafers processed during HVM. The CGI model increases inspection tool efficiency by increasing the accuracy of finding defects on the wafer with capture rates of finding defects higher than a baseline value. However, for effective and accurate defect prediction capability, the CGI model requires a full set of input data for a wafer. This may include metrology information after each processing step for a wafer. As described above, the conventional down-sampling of wafers at the lot/wafer level may cause an insufficient amount of metrology data collected for a wafer to be supplied to and train the CGI model.

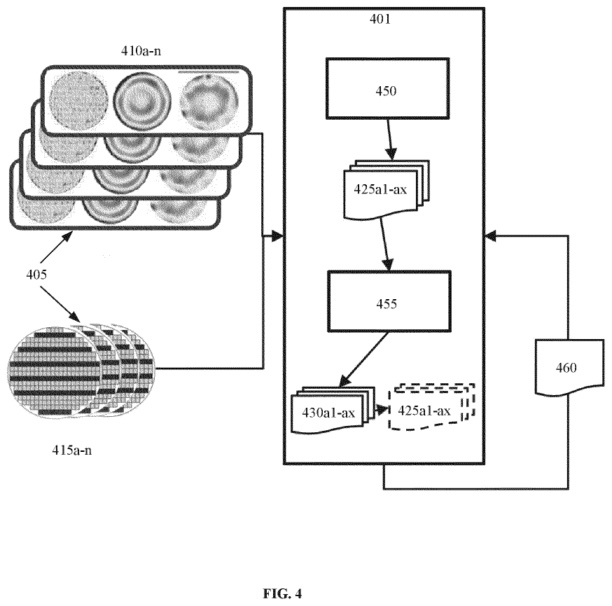

FIG. 4 is an example block diagram illustrating training of a CGI model 401 using an initial training dataset, consistent with various embodiments of the present disclosure. CGI model 401 may have to be trained using an initial training dataset 405 before it can be used to generate predictions for a wafer. The initial training dataset 405 may be a labeled dataset, which includes process-related data 410a-n and inspection results 415a-n of “n” number of substrates. For example, for a wafer “A,” the initial training dataset 405 may include process-related data 410a and inspection results 415a associated with the substrate “A.” The process-related data 410a may include metrology data such as that described above, or other such data that may contribute to a defect. The inspection results 415a may include an image of an inspected location (e.g., SEM image), location information of the inspected location (e.g., (x, y) coordinates) and whether that location is found to be defective or non-defective. The labeled dataset may be obtained from various sources, including lithographic projection apparatus 301 and inspection tool 302 of FIG. 3.

CGI model 401 may include a location prediction model 450 and a confidence model 455, both of which may be machine learning models. The training of CGI model 401 may be an iterative process in which each iteration may involve analyzing process-related data 410 associated with a wafer, determining the cost functions, and updating a configuration of CGI model 401 based on the cost function. CGI model 401 may be trained in a “batch” fashion instead of as an iterative process. For example, training dataset 405 having process-related data 410a-n and inspection results 415a-n of “n” number of substrates may be input collectively. After inputting process-related data 410a and inspection results 415a, location prediction model 450 generates predictions 425a1-425ax for “x” number of locations on wafer “A” and confidence model 455 assigns confidence scores 430a1-430ax for predictions 425a1-425ax, respectively. CGI model 401 then compares the predicted results with inspection results 415a to determine a cost function 460 of CGI model 401, which may be indicative of a deviation between predicted results 425a1-425ax and the actual inspection results 415a. CGI model 401 may update its configurations (e.g., weights, biases, or other parameters of location prediction model 450 or confidence model 455) based on cost function 460 or other reference feedback information (e.g., user indication of accuracy, reference labels, or other information) to minimize cost function 460. The above process is repeated iteratively with process-related data and inspection results associated with a different substrate in each iteration until a termination condition is satisfied. The termination condition may include a predefined number of iterations, cost function satisfies a specified threshold, or other such conditions. After the termination condition is satisfied, CGI model 401 may be considered to be “trained” and may be used for identifying or predicting defective locations in a new wafer (e.g., a wafer that has not been analyzed using CGI model 401 yet).

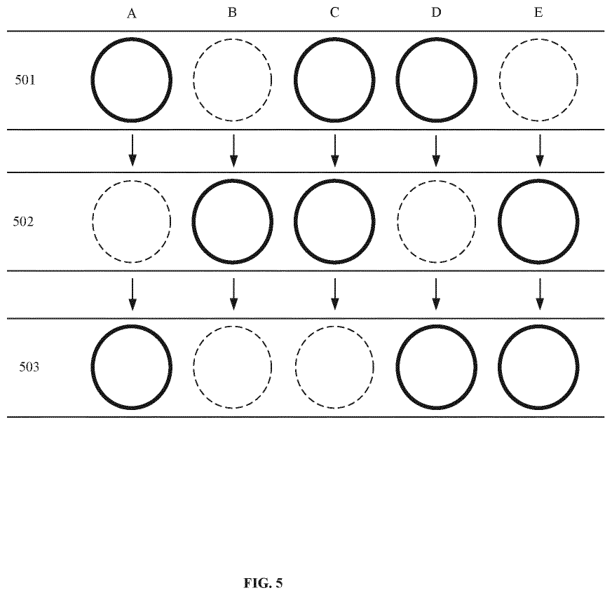

Reference is now made to FIG. 5, which is an example diagram illustrating down sampling at the lot/wafer level to acquire input metrology data for the CGI model. FIG. 5 indicates an example batch of wafers that are processed during HVM according to wafer processing step 501, wafer processing step 502, and wafer processing step 503. Each wafer processing step may correspond to a metrology applied to each of wafer A, wafer B, wafer C, wafer D, and wafer E. For example, wafer processing step 501 may be a deposition processing step, wafer processing step 502 may be a lithography processing step, and wafer processing step 503 may be an etching step. The solid, bold outline represents a wafer that is selected for metrology after a wafer processing step, and the dotted outline represents a wafer that is not selected for metrology after a wafer processing step. For example, wafer A is selected for metrology after wafer processing step 501 and wafer processing step 503. Metrology information corresponding to wafer processing step 501 and wafer processing step 503 is thus available for wafer A, but no metrology information corresponding to wafer processing step 502 is available. As a result, the input data for wafer A may not be supplied to the CGI model since there is an incomplete or insufficient input dataset (e.g., metrology information) for wafer A. As seen in FIG. 5, none of wafers A-E are measured for all wafer processing steps. Thus, according to the conventional method, none of wafers A-E in the batch may contain a sufficient dataset of metrology information to train the CGI model and subsequently generate a sampling plan to guide wafer inspection.

Embodiments of the present disclosure may provide a method to impute missing metrology information and fill in gaps of input data for the CGI model. As illustrated in FIG. 5, down-sampling at the lot/wafer level may result in missing metrology information available for the CGI model. Embodiments of the present disclosure may utilize wafer fabrication context information available for each wafer processed during wafer processing. “Fabrication context information” or “context information” may refer to the fabrication or processing information for each wafer during HVM. Each piece of equipment or apparatus used during wafer processing (e.g., lithographic projection apparatus 301 in FIG. 3) has an information log about the parameters and logistics used to process each wafer. For example, wafer A in FIG. 5 may be processed according to a context ID (e.g., a tool ID or a chamber ID) and according to a process setting (e.g., a temperature, pressure, gas mixture ratio, etc.) in wafer processing step 501 and may be processed according to a context ID and according to a process setting in wafer processing step 502. All such context information is available for each wafer processed during HVM in a fabrication database, and the fabrication database may be provided to the CGI model. The CGI model may be in communication with the fabrication database, where the context information may be queried and supplied to a CGI model platform and then linked with available metrology information for a wafer. The CGI model may be communicatively connected to the fabrication database through a medium such as an electric conductor, optical fiber cable, portable storage media, IR, Bluetooth, internet, wireless network, or wireless radio.

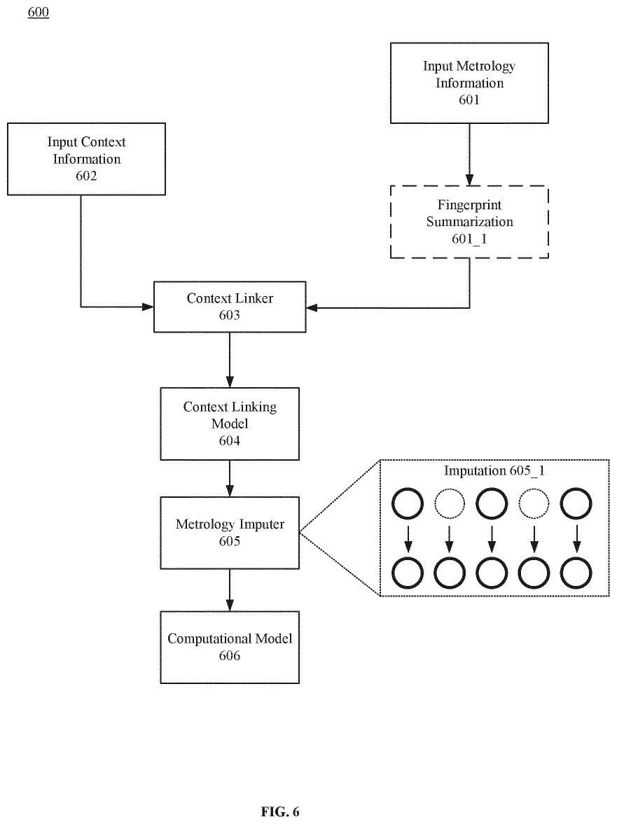

Reference is now made to FIG. 6, which is an example block diagram illustrating a system 600 with various modules that may generate a context-metrology fingerprint database and train a computational model, consistent with embodiments of the present disclosure. The modules in system 600 in FIG. 6 may be applied via controller 109 in FIG. 1, controller 290 in FIG. 2, or processor 303 in FIG. 3. The context-metrology fingerprint database may store linked context information and metrology information for a wafer processed during HVM. The fingerprint database illustrated by FIG. 6 may also be referred to as a fingerprint library. The computational model may be a CGI model.

The CGI model may obtain input metrology information 601 from a metrology tool. Input metrology information 601 may be obtained from different types of metrology tools. Example metrology tools may include but are not limited to a scatterometry tool or an inspection tool (e.g., beam tool 104 in FIG. 1 or inspection tool 302 in FIG. 3). Input metrology information 601 may be images collected for a wafer or a batch of wafers processed according to a wafer processing step (e.g., wafers A-E after wafer processing step 501 in FIG. 5). The image may contain the metrology information available for the wafers after a wafer processing step. The CGI model may also obtain input context information 602 from a fabrication database. Input context information 602 may correspond to tool ID/routing information and/or fabrication conditions or parameters applied to the wafer or batch of wafers when processed according to the wafer processing step. It is appreciated that input context information 602 is available in a fabrication database for every wafer processed according to wafer processing during HVM. Input metrology information 601, and input context information 602 may be supplied to a context linker 603, in which the CGI model evaluates input metrology information 601 for a wafer or batch of wafers processed according to input context information 602.

Context linker 603 may identify an average fingerprint in input metrology information 601 that is characteristic of input context information 602 via data mapping. For example, input metrology information 601 may be images of a batch of wafers after an etch processing step. Input context information 602 may correspondingly be a tool ID or a process parameter of an etch chamber on a etch apparatus (where the batch of wafers were processed during the etch processing step. Context linker 603 may identify an average context variable of the etch chamber that may directly lead to the result in input metrology information 601. Thus, context linker 603 outputs a model that links input context information 602 to a metrology result or an inspection result in input metrology information 601. Context linker 603 may output a context linking model 604 for each type of metrology information available for a wafer (e.g., etch, CD, overlay, etc.). A context linking model may be generated for each type of metrology information available for a batch of wafers processed according to wafer processing to generate a library of context linking models that link a particular metrology result to a wafer processing step during HVM. If context information is known for a wafer processed according to a processing step, then a context linking model previously generated by context linker 603 may be applied to impute a metrology result that is missing for a wafer.

To perform the imputation, metrology imputer 605 reads input metrology information 601 or input context information 602 and applies the corresponding context linking model 604 from the generated context linking model library. Metrology imputer 605 may perform an example imputation 605_1 to impute missing information (e.g., metrology information) for a dataset of wafers. As illustrated in example imputation 605_1, a dotted circle represents a wafer with missing information (e.g., metrology information), and a solid circle represents a wafer with available information (e.g., metrology information and context information). Metrology imputer 605 may perform example imputation 605_1 by reading the available information (e.g., input context information 602) for a wafer represented by the dotted circle and applying the corresponding context linking model (e.g., context linking model 604) to impute the missing information (e.g., input metrology information 601). Metrology imputer 605 then supplies the imputed, complete dataset of wafers to a computational model 606. The imputed dataset supplied by metrology imputer 605 may be used to train computational model 606. The imputed dataset may thus be referred to as a training dataset. Training computational model 606 may be as described above for FIG. 4

Input metrology information 601 may optionally be processed before being provided to context linker 603 via fingerprint summarization 601_1. Input metrology information 601 may contain an excess of high-frequency noise that may not be related to context information 602. Fingerprint summarization 601_1 is a technique to reduce noise in input metrology information 601 and filter out high-frequency noise or random variation (e.g., wafer to wafer variation in a batch of wafers) from input metrology information 601 and keep systematic, context-induced variation in input metrology information 601. Non-limiting examples of fingerprint summarization 601_1 may include principal component analysis (PCA), factor analysis, wafer map modeling using a Zernike polynomial, edge model analysis, or other dimensionality reduction methods to reduce high-frequency noise or random variation in data.

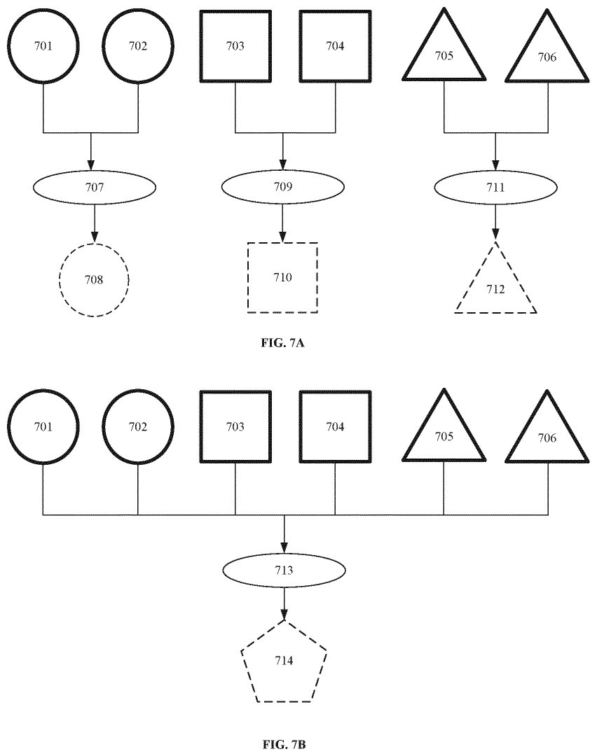

Reference is now made to FIG. 7A, which is an example illustration of imputing metrology information for wafers that were not measured after a wafer processing step, consistent with embodiments of the present disclosure. The circles, squares, and triangles with solid outlines represent wafers that were processed to a certain wafer processing step or processing apparatus (e.g., context information) and measured (e.g., metrology information available). For example, wafer 701 and wafer 702 may be processed according to an etch processing step, wafer 703 and wafer 704 may be processed according to a deposition processing step, wafer 705 and wafer 706 may be processed according to an overlay processing step, and metrology information may be available for wafers 701-706. The context average fingerprint, or context linking model, may be calculated for each set of wafers as described above in FIG. 6. Then, a metrology imputer (e.g., metrology imputer 605 in FIG. 6) applies context averaged fingerprint 707 to a wafer 708 that was processed according to the same processing step as wafer 701 and wafer 702 but was not measured (e.g., no metrology information is available) to impute metrology information for “missing” wafer 708. The metrology imputer may also apply context average fingerprint 709 to a wafer 710 and context average fingerprint 711 to a wafer 712 to impute metrology information for “missing” wafer 710 and “missing” wafer 712, respectively. The process illustrated in FIG. 7A may be referred to as “context-based imputation.” The imputed metrology information for “missing” wafers 708, 710, and 712 and the metrology information for wafers 701-706 may then be supplied as a training dataset to the CGI model. The CGI model may then apply the imputation to a subsequent wafer that was not measured during HVM to generate a sampling plan to guide wafer inspection using the built context linking model. Wafers 701-706 may also represent wafers fabricated according to different process settings. For example, wafer 701 and wafer 702 may be fabricated at wafer processing step 701 at a temperature, pressure, gas mixture ratio, or other continuous variables. Wafer 703 and wafer 704 may be fabricated at wafer processing step 702 at another temperature, pressure, gas mixture, or other continuous variables. The CGI model may apply context-based imputation as illustrated in FIG. 7A to impute metrology information for missing wafers 708, 710, and 712 according to the context average of such process settings available for wafers 701-706.

Reference is now made to FIG. 7B, which is an example illustration of imputing missing information for a wafer using a global imputation, consistent with embodiments of the present disclosure. In some embodiments, a wafer used to train the CGI model may not have metrology information and may have new context information. For example, a “missing” wafer 714 (e.g., no metrology information) may have been processed by a different process chamber than wafers 701-706. A context averaged fingerprint may not be used to impute the missing metrology information for “missing” wafer 714 since the context information for wafer 714 was not used to build the context-metrology fingerprint database. Thus, a global average fingerprint 713 may be calculated for all wafers 701-706 and be used to impute the metrology information for “missing” wafer 714. In some embodiments, wafer 714 may not have metrology information, and the context information may be missing from the fabrication database (e.g., fabrication database described above). Thus, a context averaged fingerprint may not be used to impute the missing metrology information for “missing” wafer 714. Instead, the global average fingerprint 713 may be calculated for all wafers 701-706 and used to impute the missing metrology information for “missing” wafer 714.

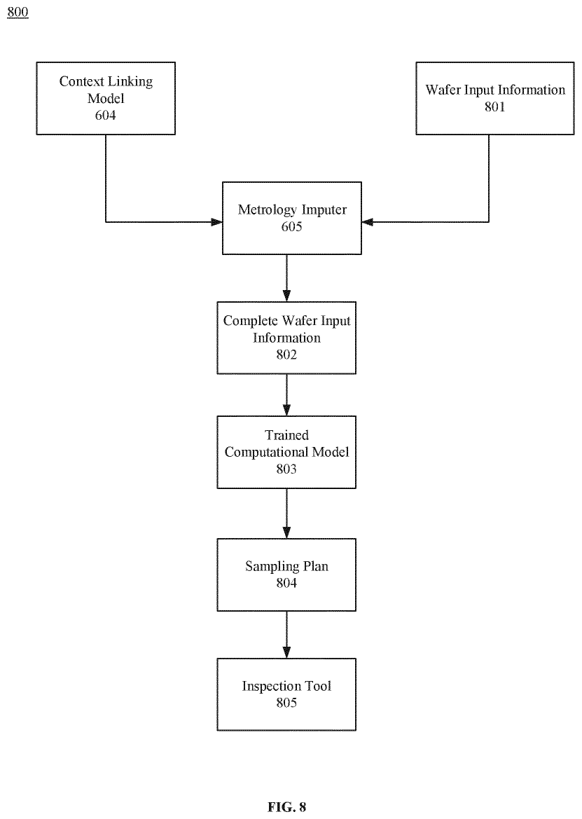

Reference is now made to FIG. 8, which is an example block diagram illustrating a system 800 applying the trained computational model to generate a sampling plan for a wafer and guide wafer inspection, consistent with embodiments of the present disclosure. As illustrated in FIG. 8, wafer input information 801 may be supplied to metrology imputer 605.

Wafer input information 801 may include metrology information or context information for a wafer not used in the training dataset in FIG. 6, and wafer input information 801 may be incomplete (e.g., missing metrology information). Context linking model 604 may also be supplied to metrology imputer 605, and metrology imputer 605 may impute complete wafer input information 802. As described above, context linking model 604 may identify the corresponding context information of wafer input information 801 and metrology imputer 605 may impute missing information from wafer input information 801 (e.g., missing metrology information). Complete wafer input information 802 may then be supplied to trained computational model 803 and trained computational model 803 may determine defective die probability for each die of the wafer using the complete wafer input information 802. A sampling plan 804 may then be generated and supplied to an inspection tool 805 (e.g., EBI system in FIG. 1, multi-beam tool 104 in FIG. 2, or inspection tool 302 in FIG. 3) to guide wafer inspection of the wafer.

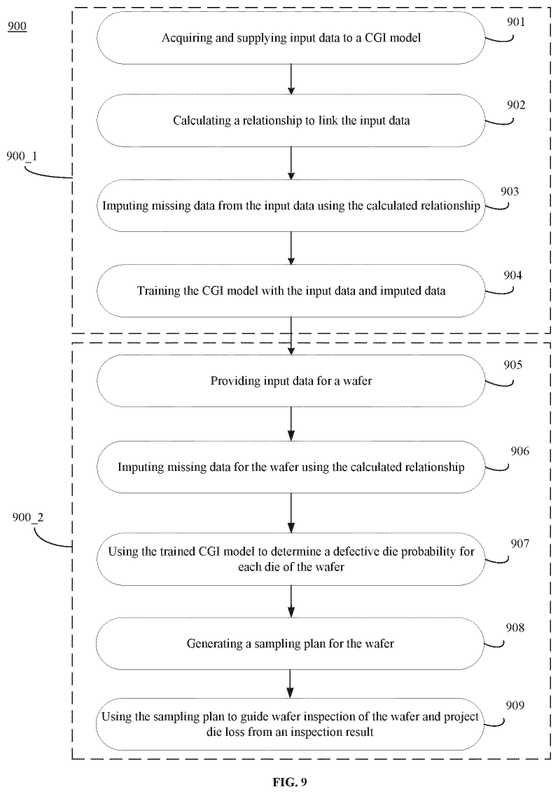

Reference is now made to FIG. 9, which is an example flow diagram illustrating a method 900 of generating a context linked model to impute missing input data for a CGI model and using the CGI model to generate a sampling plan for wafer inspection, consistent with embodiments of the present disclosure. The steps of method 900 may be performed by a computing device, e.g., controller 109 of FIG. 1, controller 290 of FIG. 2, or processor 303 of FIG. 3. It is appreciated that the illustrated method 900 may be altered to modify the order of steps and to include the additional steps.

Steps 901 to 904 of method 900 may be considered a training phase 900_1, and steps 905 to 908 of method 900 may be considered an application phase 900_2. Training phase 900_1 may be performed by system 600 in FIG. 6, and application phase 900_2 may be performed by system 800 in FIG. 8. In some embodiments, the same system can perform training phase 900_1 and application phase 900_2.

In step 901, input data is acquired and supplied to the CGI model (e.g., CGI model 401). The input data may be metrology information available for a batch of wafers that are measured after a wafer processing step. The metrology information (e.g., input metrology information 601 of FIG. 6) may optionally be processed to reduce the dimensionality of the dataset as described above (e.g., fingerprint summarization). Each of the wafers in the batch of wafers have context information (e.g., input context information 602 of FIG. 6). The CGI model may acquire the context information from a fabrication database as described above.

In step 902, a relationship is calculated to link the input data. This relationship may be a context linking model (e.g., context linking model 604 of FIG. 6) that links the context information for a wafer to a particular fingerprint or residual in the metrology data collected after a wafer processing step. For example, the context linking model may identify a characteristic in the metrology data present after an etching processing step is applied to a wafer. The characteristic in the metrology data may be, for example, a characteristic spatial fingerprint of the metrology data. A context linking model may be a context average fingerprint (e.g., context average fingerprint 707, 709, or 711 of FIG. 7A) or a global average fingerprint (e.g., global average fingerprint 713 of FIG. 7B). A context average fingerprint is calculated to link all wafers with metrology information available that were processed according to the same wafer processing step (e.g., have the same context information). A global average fingerprint is calculated to link all wafers with metrology information available. A library of context linking models that link all available metrology information with context information is generated.

In step 903, missing data from the input data is imputed using the calculated relationship. The missing data may be metrology information for a wafer with known context information that was not measured after a wafer processing step and may be imputed using the context average fingerprint. The missing data may be metrology information for a wafer with unknown context information that was not measured after a wafer processing step. The missing metrology information may be imputed using the global average fingerprint.

In step 904, the CGI model is trained with the input data and the imputed data. Training the CGI model may be as described above for FIG. 4.

In step 905, input data for a wafer is provided to the CGI model. The input data may be wafer input information 801 as illustrated in FIG. 8 and may be incomplete (e.g., missing metrology information or both metrology information and context information). In step 906, missing data from the input data of the wafer is imputed using the calculated relationship determined in step 902.

In step 907, the imputed data and input data of the wafer are supplied to the trained CGI model, and the trained CGI model determines a defective die probability for each die of the wafer. In step 908, a sampling plan is generated using the defective die probability for each die calculated in step 907. In step 909, the generated sampling is used to guide wafer inspection of the wafer and a die loss is projected from an inspection result.

Reference is now made to Table 1, which displays R² correlation scores and area under receiver operating characteristic (AUC) scores for a context average imputation and a global average imputation applied to a dataset of twelve wafers (e.g., method 900 of the present disclosure). Specifically, the dataset comprises a batch of twelve wafers that sampling plans were generated to guide inspection according to method 900 of the present disclosure. A sampling plan was generated by the CGI model applying either context average imputation or global average imputation to generate missing data for a wafer. A projected die loss was calculated, and a probe test result was obtained from the twelve wafers of the dataset.

TABLE 1
Quantification of R² correlation and AUC scores
of the CGI model when applying a context average
imputation or a global average imputation.

| | Context Average | Global Average |
|---|---|---|
| Performance Metric | Imputation | Imputation |
| R² correlation score | 0.90 | 0.86 |
| AUC score | 0.76 | 0.74 |

A benefit provided by embodiments of the present disclosure may be an improved accuracy in predicting defective die in wafers fabricated during HVM. In some embodiments, a statistical data imputation technique is used to estimate missing metrology measurement results from wafer fabrication information. In some embodiments, a computational model is provided that may further improve the accuracy of a CGI-generated projected die loss and R² correlation score. Some embodiments of the present disclosure may provide a method to improve a CGI model performance and versatility to guide wafer inspection. Some embodiments of the present disclosure may provide a method to increase defect inspection accuracy and yield of defect-free wafers throughout HVM.

A non-transitory computer readable medium may be provided that may store instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, store instructions for a processor of a lithographic projection apparatus (e.g., lithographic projection apparatus 301 of FIG. 3) and inspection tool (e.g., inspection tool 302 of FIG. 3) to determine input data of a sample, perform method 900 of FIG. 9, and other executable functions relating to identifying locations on a wafer for inspection during HVM. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method of identifying a location on a wafer to scan during inspection using a computational defect probability model, the method comprising:
obtaining initial metrology data and initial context data for a plurality of initial wafers; and correlating the initial metrology data and the initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.
2. The method of clause 1, wherein correlating the initial metrology data and initial context data for the plurality of wafers determines a link between the initial metrology data and initial context data.
3. The method of clause 1 or 2, wherein the initial metrology data is a metrology result or an inspection result.
4. The method of clause 1 or 2, wherein the initial context data is wafer fabrication data associated with a wafer processing step.
5. The method of any one of clauses 1 to 4, wherein metrology data is imputed for the subsequent wafer based on the correlation with the plurality of initial wafers.
6. The method of any one of clauses 1 to 5, wherein the inspection tool is a scanning charged particle microscope or an optical tool.
7. The method of any one of clauses 1 to 6, wherein the computational defect probability model is a computational guided inspection model.
8. A method of identifying a location on a wafer to scan during inspection, the method comprising: obtaining initial metrology data and initial context data for a plurality of wafers;
correlating the initial metrology data and initial context data for each wafer of the plurality of wafers;
imputing missing data from the plurality of wafers using the correlated initial metrology data and initial context data; and
training a computational defect probability model with the imputed missing data and initial metrology data and initial context data for the plurality of wafers.
9. The method of clause 8, wherein correlating the initial metrology data and initial context data for the plurality of wafers determines a link between the initial metrology data and initial context data.
10. The method of clause 8 or 9, wherein the initial metrology data is a metrology result or an inspection result.
11. The method of clause 8 or 9, wherein the initial context data is wafer fabrication data associated with a wafer processing step.
12. The method of any one of clauses 8 to 11, wherein the imputed missing data for the plurality of wafers is metrology data.
13. The method of clause 8, further comprising:
providing input data for a wafer to the trained computational defect probability model;
imputing missing data for the wafer using the correlated initial metrology data and initial context data of the plurality of wafers;
using the trained computational defect probability model to determine a defective die probability for each die of the wafer from the imputed missing data and input data for the wafer;
generating a sampling plan for the wafer; and
using the sampling plan to guide an inspection tool for wafer inspection of the wafer.
14. The method of clause 13, wherein the imputed missing data for the wafer is metrology data.
15. The method of clause 14, wherein the metrology data is metrology result or an inspection result.
16. The method of any one of clauses 13 to 15, wherein the input data for the wafer is metrology data or context data.
17. The method of any one of clauses 13 to 16, wherein the inspection tool is a scanning charged particle microscope or an optical tool.
18. The method of any one of clauses 8 to 17, wherein the computational defect probability model is a computational guided inspection model.
19. An apparatus for identifying a location on a wafer to scan during inspection using a computational defect probability model, comprising:
a memory storing a set of instructions; and
at least one processor configured to execute the set of instructions to cause the apparatus to perform operations comprising:
obtaining initial metrology data and initial context data for a plurality of initial wafers; and
correlating the initial metrology data and initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.
20. The apparatus of clause 19, wherein correlating the initial metrology data and initial context data for the plurality of wafers determines a link between the initial metrology data and initial context data.
21. The apparatus of clause 19 or 20, wherein the initial metrology data is a metrology result or an inspection result.
22. The apparatus of clause 19 or 20, wherein the initial context data is wafer fabrication data associated with a wafer processing step.
23. The apparatus of any one of clauses 19 to 22, wherein metrology data is imputed for the subsequent wafer based on the correlation with the plurality of initial wafers.
24. The apparatus of any one of clauses 19 to 23, wherein the inspection tool is a scanning charged particle microscope or an optical tool.
25. The apparatus of any one of clauses 19 to 24, wherein the computational defect probability model is a computational guided inspection model.
26. An apparatus for identifying a location on a wafer to scan during inspection using a computational defect probability model, comprising:
a memory storing a set of instructions; and
at least one processor configured to execute the set of instructions to cause the apparatus to perform operations comprising:
obtaining initial metrology data and initial context data for a plurality of wafers;
correlating the initial metrology data and initial context data for each wafer of the plurality of wafers;
imputing missing data from the plurality of wafers using the correlated initial metrology data and initial context data; and
training a computational defect probability model with the imputed missing data and initial metrology data and initial context data for the plurality of wafers.
27. The apparatus of clause 26, wherein correlating the initial metrology data and initial context data for the plurality of wafers determines a link between the initial metrology data and initial context data.
28. The apparatus of clause 26 or 27, wherein the initial metrology data is a metrology result or an inspection result.
29. The apparatus of clause 26 or 27, wherein the initial context data is wafer fabrication data associated with a wafer processing step.
30. The apparatus of any one of clauses 26 to 29, wherein the imputed missing data for the plurality of wafers is metrology data.
31. The apparatus of clause 26, wherein the operations further comprise:
providing input data for a wafer to the trained computational defect probability model; imputing missing data for the wafer using the correlated initial metrology data and initial context data of the plurality of wafers;
using the trained computational defect probability model to determine a defective die probability for each die of the wafer from the imputed missing data and input data for the wafer;
generating a sampling plan for the wafer; and
using the sampling plan to guide an inspection tool for wafer inspection of the wafer.
32. The apparatus of clause 31, wherein the imputed missing data for the wafer is metrology data.
33. The apparatus of clause 32, wherein the metrology data is a metrology result or an inspection result.
34. The apparatus of any one of clauses 31 to 33, wherein the input data for the wafer is metrology data or context data.
35. The apparatus of any one of clauses 31 to 34, wherein the inspection tool is a scanning charged particle microscope or an optical tool.
36. The apparatus of any one of clauses 26 to 35, wherein the computational defect probability model is a computational guided inspection model.
37. A non-transitory computer readable medium comprising a set of instructions that is executable by one or more processors of a computing device to cause the computing device to perform operations for identifying a location on a wafer to scan during inspection using a computational defect probability model, the operations comprising:
obtaining initial metrology data and initial context data for a plurality of initial wafers; and
correlating the initial metrology data and initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.
38. The non-transitory computer readable medium of clause 37, wherein correlating the initial metrology data and initial context data for the plurality of wafers determines a link between the initial metrology data and initial context data.
39. The non-transitory computer readable medium of clause 37 or 38, wherein the initial metrology data is a metrology result or an inspection result.
40. The non-transitory computer readable medium of clause 37 or 38, wherein the initial context data is wafer fabrication data associated with a wafer processing step.
41. The non-transitory computer readable medium of any one of clauses 37 to 40, wherein metrology data is imputed for the subsequent wafer based on the correlation with the plurality of initial wafers.
42. The non-transitory computer readable medium of any one of clauses 37 to 41, wherein the inspection tool is a scanning charged particle microscope or an optical tool.
43. The non-transitory computer readable medium of any one of clauses 37 to 42, wherein the computational defect probability model is a computational guided inspection model.
44. A non-transitory computer readable medium comprising a set of instructions that is executable by one or more processors of a computing device to cause the computing device to perform operations for identifying a location on a wafer to scan during inspection, the operations comprising: obtaining initial metrology data and initial context data for a plurality of wafers;
correlating the initial metrology data and initial context data for each wafer of the plurality of wafers;
imputing missing data from the plurality of wafers using the correlated initial metrology data and initial context data; and
training a computational defect probability model with the imputed missing data and initial metrology data and initial context data for the plurality of wafers.
45. The non-transitory computer readable medium of clause 44, wherein correlating the initial metrology data and initial context data for the plurality of wafers determines a link between the initial metrology data and initial context data.
46. The non-transitory computer readable medium of clause 44 or 45, wherein the initial metrology data is a metrology result or an inspection result.
47. The non-transitory computer readable medium of clause 44 or 45, wherein the initial context data is wafer fabrication data associated with a wafer processing step.
48. The non-transitory computer readable medium of any one of clauses 44 to 47, wherein the imputed missing data for the plurality of wafers is metrology data.
49. The non-transitory computer readable medium of clause 44, wherein the operations further comprise:
providing input data for a wafer to the trained computational defect probability model;
imputing missing data for the wafer using the correlated initial metrology data and initial context data of the plurality of wafers;
using the trained computational defect probability model to determine a defective die probability for each die of the wafer from the imputed missing data and input data for the wafer;
generating a sampling plan for the wafer; and
using the sampling plan to guide an inspection tool for wafer inspection of the wafer.
50. The non-transitory computer readable medium of clause 49, wherein the imputed missing data for the wafer is metrology data.
51. The non-transitory computer readable medium of clause 50, wherein the metrology data is a metrology result or an inspection result.
52. The non-transitory computer readable medium of any one of clauses 49 to 51, wherein the input data for the wafer is metrology data or context data.
53. The non-transitory computer readable medium of any one of clauses 49 or 52, wherein the inspection tool is a scanning charged particle microscope or an optical tool.
54. The non-transitory computer readable medium of any one of clauses 44 to 53, wherein the computational defect probability model is a computational guided inspection model.
55. An inspection system using a computational model to identify a location on a wafer to scan during inspection, the inspection system comprising:
one or more processors configured to execute instructions to cause the inspection system to perform: obtaining initial metrology data and initial context data for a plurality of initial wafers; and
correlating the initial metrology data and initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, and other embodiments will be apparent to those skilled in the art from consideration of the specification and practice of the technology disclosed herein. It is intended that the specification and examples be considered as exemplary only, with a true scope and spirit of the disclosure being indicated by the following claims.

1. An apparatus for identifying a location on a wafer to scan during inspection using a computational defect probability model, comprising:
a memory storing a set of instructions; and
at least one processor configured to execute the set of instructions to cause the apparatus to perform operations comprising:
obtaining initial metrology data and initial context data for a plurality of initial wafers;
correlating the initial metrology data and initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.

2. The apparatus of claim 1, wherein correlating the initial metrology data and initial context data for the plurality of initial wafers determines a link between the initial metrology data and initial context data.

3. The apparatus of claim 1, wherein the initial metrology data is a metrology result or an inspection result.

4. The apparatus of claim 1, wherein the initial context data is wafer fabrication data associated with a wafer processing step.

5. The apparatus of claim 1, wherein metrology data is imputed for the subsequent wafer based on the correlation with the plurality of initial wafers.

6. The apparatus of claim 1, wherein the inspection tool is a scanning charged particle microscope or an optical tool.

7. The apparatus of claim 1, wherein the computational defect probability model is a computational guided inspection model.

8. A non-transitory computer readable medium comprising a set of instructions that is executable by one or more processors of a computing device to cause the computing device to perform operations for identifying a location on a wafer to scan during inspection, the operations comprising:
obtaining initial metrology data and initial context data for a plurality of wafers;
correlating the initial metrology data and initial context data for each wafer of the plurality of wafers;
imputing missing data from the plurality of wafers using the correlated initial metrology data and initial context data; and
training a computational defect probability model with the imputed missing data and initial metrology data and initial context data for the plurality of wafers.

9. The non-transitory computer readable medium of claim 8, wherein correlating the initial metrology data and initial context data for the plurality of wafers determines a link between the initial metrology data and initial context data.

10. The non-transitory computer readable medium of claim 8, wherein the initial metrology data is a metrology result or an inspection result.

11. The non-transitory computer readable medium of claim 8, wherein the initial context data is wafer fabrication data associated with a wafer processing step.

12. The non-transitory computer readable medium of claim 8, wherein the imputed missing data for the plurality of wafers is metrology data.

13. The non-transitory computer readable medium of claim 8, wherein the operations further comprise:
providing input data for a wafer to the trained computational defect probability model;
imputing missing data for the wafer using the correlated initial metrology data and initial context data of the plurality of wafers;
using the trained computational defect probability model to determine a defective die probability for each die of the wafer from the imputed missing data and input data for the wafer;
generating a sampling plan for the wafer; and
using the sampling plan to guide an inspection tool for wafer inspection of the wafer.

14. The non-transitory computer readable medium of claim 13, wherein the imputed missing data for the wafer is metrology data.

15. The non-transitory computer readable medium of claim 14, wherein the metrology data is a metrology result or an inspection result.

16. A non-transitory computer readable medium comprising a set of instructions that is executable by one or more processors of a computing device to cause the computing device to perform operations for identifying a location on a wafer to scan during inspection using a computational defect probability model, the operations comprising:
obtaining initial metrology data and initial context data for a plurality of initial wafers; and
correlating the initial metrology data and initial context data for each wafer of the plurality of initial wafers;
correlating a subsequent wafer with the plurality of initial wafers based on context data of the subsequent wafer and the initial context data of the plurality of initial wafers; and
selecting a location on the subsequent wafer to scan using an inspection tool based on the correlation.

17. The non-transitory computer readable medium of claim 16, wherein correlating the initial metrology data and initial context data for the plurality of initial wafers determines a link between the initial metrology data and initial context data.

18. The non-transitory computer readable medium of claim 16, wherein the initial metrology data is a metrology result or an inspection result.

19. The non-transitory computer readable medium of claim 16, wherein the initial context data is wafer fabrication data associated with a wafer processing step.

20. The non-transitory computer readable medium of claim 16, wherein metrology data is imputed for the subsequent wafer based on the correlation with the plurality of initial wafers.
